(19) United States
(12) Patent Application Publication
(10) Pub. No.: US 2025/0328281 A1
(43) Pub. Date: Oct. 23, 2025

(54) MEMORY SYSTEMS AND METHODS OF OPERATING MEMORY SYSTEMS, ELECTRONIC APPARATUSES, AND COMPUTER READABLE STORAGE MEDIUMS THEREOF

(71) Applicant: YANGTZE MEMORY TECHNOLOGIES CO., LTD., Wuhan (CN)

(72) Inventors: Suyi LIU, Wuhan (CN); Lu GUO, Wuhan (CN)

(21) Appl. No.: 19/012,168

(22) Filed: Jan. 7, 2025

(30) Foreign Application Priority Data
Apr. 19, 2024 (CN) 2024104800298

(51) Int. Cl. G06F 3/06

(52) U.S. Cl. CPC G06F 3/0656; G06F 3/0619; G06F 3/0659; G06F 3/0679

(57) ABSTRACT

Examples of the present disclosure disclose memory systems, methods of operating memory systems, electronic apparatuses, and computer readable mediums. The example memory system includes a memory and a memory controller. The memory includes a memory cell array and a peripheral circuit coupled with the memory cell array, the peripheral circuit including a page buffer. The memory controller is configured to: in response to a first read request including a first logical address, read data from the memory cell array, and store the read data through the page buffer, where the data includes all data stored in a physical page to which a first physical address corresponding to the first logical address points; and in response to a second read request including a second logical address, read data corresponding to the second logical address from the page buffer, where the second logical address is related to the first logical address.

### CROSS-REFERENCE TO RELATED APPLICATIONS

The present application claims priority to Chinese Patent Application No. 2024104800298, which was filed Apr. 19, 2024, and is hereby incorporated herein by reference in its entirety.

### TECHNICAL FIELD

Examples of the present disclosure relate to the technical field of memories, and relate to, but are not limited to, a memory and an operation method thereof, a memory system, and an electronic apparatus.

### BACKGROUND

Memories are classified into volatile memories and non-volatile memories depending on whether stored data is retained in the case of a power failure. The non-volatile memories retaining data in the case of a power failure may include a Read-Only Memory (abbreviated as ROM), an Electrically Erasable and Programmable ROM (abbreviated as EEPROM), and a flash memory, etc.

As the demand for the storage density increases continuously, the industry has developed three-dimensional memories having three-dimensional structures (e.g., 3D NAND), to increase the storage density through a three-dimensional arrangement of memory cells. However, the increase in the storage density leads to more data read problems.

### SUMMARY

According to a first aspect of examples of the present disclosure, a memory system is provided, including: a memory including a memory cell array and a peripheral circuit coupled with the memory cell array, the peripheral circuit including a page buffer; and a memory controller coupled with the memory and configured to: in response to a first read request including a first logical address, read data from the memory cell array, and store the read data through the page buffer, wherein the data includes all data stored in a physical page to which a first physical address corresponding to the first logical address points; and in response to a second read request including a second logical address, read data corresponding to the second logical address from the page buffer, wherein the second logical address is related to the first logical address.

According to a second aspect of examples of the present disclosure, a method of operating a memory system is provided, wherein the memory system includes a memory and a memory controller coupled with the memory; the memory includes a memory cell array and a peripheral circuit coupled with the memory cell array, the peripheral circuit including a page buffer; the method includes: in response to a first read request including a first logical address, controlling the peripheral circuit to read data stored in the memory cell array, and storing the read data through the page buffer, wherein the data includes all data stored in a physical page to which a first physical address corresponding to the first logical address points; and in response to a second read request including a second logical address, controlling the peripheral circuit to read data corresponding to the second logical address in the page buffer, wherein the second logical address is related to the first logical address.

According to a third aspect of examples of the present disclosure, an electronic apparatus is provided, including:
the memory system of any example in the first aspect of examples of the present disclosure; and
a host coupled with the memory system.

According to a fourth aspect of examples of the present disclosure, a computer readable storage medium is provided, storing instructions that, when executed by a processor, implement the method of any example in the second aspect of examples of the present disclosure.

In the examples of the present disclosure, the memory controller is configured to: in response to the first read request including the first logical address, read the data from the memory cell array, and store the read data through the page buffer, wherein the data includes the all data stored in the physical page to which the first physical address corresponding to the first logical address points; and in response to the second read request including the second logical address, read the data corresponding to the second logical address from the page buffer, wherein the second logical address is related to the first logical address.

### BRIEF DESCRIPTION OF THE DRAWINGS

In the accompanying drawings, unless otherwise specified, identical or similar components or elements are represented by a like numeral throughout several drawings. These drawings are not necessarily drawn to scale. It is to be understood that, these drawings merely describe some implementations disclosed according to examples of the present application, and should not be considered as limiting the scope of the present application.

FIG. 1 is a schematic diagram illustrating an electronic apparatus according to examples of the present disclosure.

FIG. 2A is a schematic diagram illustrating a memory card according to examples of the present disclosure.

FIG. 2B is a schematic diagram illustrating a solid-state disk according to examples of the present disclosure.

FIG. 3 is a schematic block diagram illustrating a three-dimensional NAND memory according to examples of the present disclosure.

FIG. 4 is a schematic cross-sectional view illustrating a memory according to examples of the present disclosure.

FIG. 5 is a schematic diagram illustrating a memory including a memory cell array and a peripheral circuit according to examples of the present disclosure.

FIG. 6 is a schematic diagram illustrating a memory system according to examples of the present disclosure.

FIG. 7 is a schematic diagram of reading stored data from a page buffer according to examples of the present disclosure.

FIG. 8 is a flow diagram illustrating a method of operating a memory system according to examples of the present disclosure.

### DETAILED DESCRIPTION

For ease of understanding of the present disclosure, example implementations of the present disclosure will be described below in more detail with reference to the relevant drawings. Although the example implementations of the present disclosure are shown in the drawings, it is to be understood that the present disclosure may be achieved in various forms which should not be limited by particular implementations as set forth herein. Rather, these implementations are provided for a more thorough understanding of the present disclosure, and can fully convey the scope of the present disclosure to those skilled in the art.

In the following description, numerous specific details are presented to provide a more thorough understanding of the present disclosure. However, it is apparent to those skilled in the art that the present disclosure may be implemented without one or more of these details. In some examples, in order to avoid confusing with the present disclosure, some technical features well-known in the art are not described; for example, not all features of actual examples are described herein, and well-known functions and structures are not described in detail.

In general, terminologies may be understood at least in part from usage in the context. For example, the term “one or more” as used herein, depending at least in part upon the context, can be used to describe any feature, structure, or characteristic in a singular sense or can be used to describe combinations of features, structures, or characteristics in a plural sense. Similarly, terms, such as “a/an” or “the”, likewise can be understood as conveying a singular use or a plural use, depending at least in part upon the context. In addition, the term “based on” may be understood as being not necessarily intended to convey an exclusive set of factors and may, instead, allow for existence of additional factors not necessarily described expressly, likewise depending at least in part upon the context.

The terms as used herein are only intended to describe the particular examples, and are not used as limitations to the present disclosure, unless otherwise defined. As used herein, unless otherwise indicated expressly in the context, “a”, “one” and “the” in a singular form are also intended to include a plural form. The terms “consist of”, “include”, and/or “comprise”, when used in this specification, determine the presence of the described features, integers, steps, operations, elements and/or components, but do not preclude the presence or addition of one or more of other features, integers, steps, operations, elements, components, and/or groups. As used herein, the term “and/or” includes any and all combinations of related items listed.

In order to understand the present disclosure thoroughly, detailed steps and detailed structures will be proposed in the following description to set forth the technical solution of the present disclosure. The detailed descriptions of some examples of the present disclosure are as follows. However, the present disclosure may also have other implementations in addition to these detailed descriptions.

A memory in the examples of the present disclosure includes, but is not limited to, a three-dimensional NAND memory. For ease of understanding, the three-dimensional NAND memory is used as an example for description.

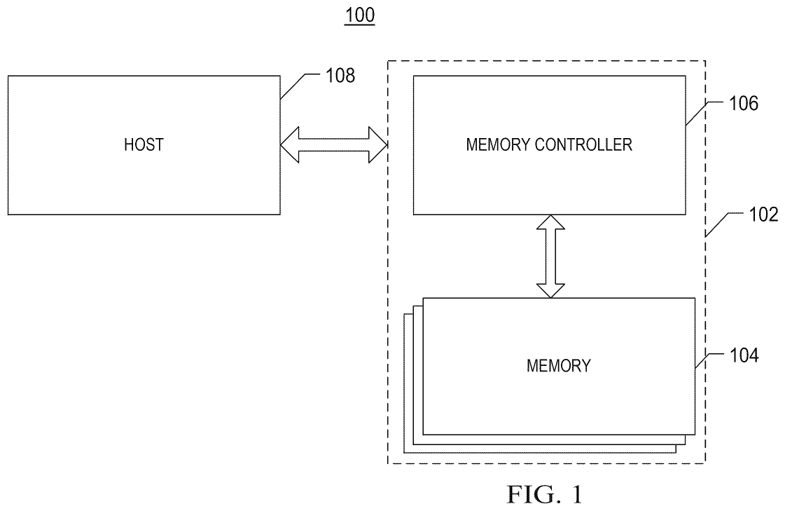

FIG. 1 is a schematic diagram illustrating an electronic apparatus 100 according to examples of the present disclosure. The electronic apparatus 100 may be a mobile phone, a desktop computer, a laptop computer, a tablet computer, a vehicle computer, a gaming console, a printer, a positioning apparatus, a wearable electronic apparatus, a smart sensor, a Virtual Reality (abbreviated as VR) apparatus, an Augmented Reality (abbreviated as AR) apparatus, or any other suitable electronic apparatuses having memories therein. As shown in FIG. 1, the electronic apparatus 100 may include a host 108 and a memory system 102, wherein the memory system 102 has one or more memories 104 and a memory controller 106. The host 108 may be a processor (e.g., a Central Processing Unit (abbreviated as CPU)) or a System on Chip (abbreviated as SOC) (e.g., an Application Processor (abbreviated as AP)) of the electronic apparatus. The host 108 may be configured to send or receive data to or from the memory 104.

According to some implementations, the memory controller 106 is coupled to the memory 104 and the host 108, and configured to control the memory 104. The memory controller 106 can manage data stored in the memory 104 and communicate with the host 108. In some implementations, the memory controller 106 is designed for operating in a low duty-cycle environment, such as a Secure Digital (abbreviated as SD) card, a Compact Flash (abbreviated as CF) card, a Universal Serial Bus (abbreviated as USB) flash drive, or other medium for use in electronic apparatuses such as a personal computer, a digital camera, and a mobile phone. In some implementations, the memory controller 106 is designed for operating in a high duty-cycle environment, such as a Solid-State Disk (abbreviated as SSD) or an embedded Multi-Medium Card (abbreviated as eMMC), which is used as a data memory for mobile apparatuses such as a smartphone, a tablet computer, and a laptop computer, and an enterprise memory array.

The memory controller 106 may be configured to control operations of the memory 104, such as read, erase, and program operations. The memory controller 106 may further be configured to manage various functions with respect to data stored or to be stored in the memory 104, including, but not limited to, bad-block management, garbage collection, logical-to-physical address conversion, wear leveling, etc. In some implementations, the memory controller 106 is further configured to process an Error Correction Code (abbreviated as ECC) with respect to data read from or written to the memory 104. The memory controller 106 may also perform any other suitable functions, e.g., formatting the memory 104. The memory controller 106 may communicate with an external apparatus (e.g., the host 108 in FIG. 1) according to a particular communication protocol. For example, the memory controller 106 may communicate with the external apparatus through at least one of various interface protocols, such as a USB protocol, an MMC protocol, a Peripheral Component Interconnection (abbreviated as PCI) protocol, a Peripheral Component Interconnect Express (PCI Express, abbreviated as PCI-E) protocol, an Advanced Technology Attachment (abbreviated as ATA) protocol, a serial-ATA protocol, a parallel-ATA protocol, a Small Computer System Interface (abbreviated as SCSI) protocol, an Enhanced Small Disk Interface (abbreviated as ESDI) protocol, an Integrated Development Equipment (abbreviated as IDE) protocol, and a Firewire protocol, etc.

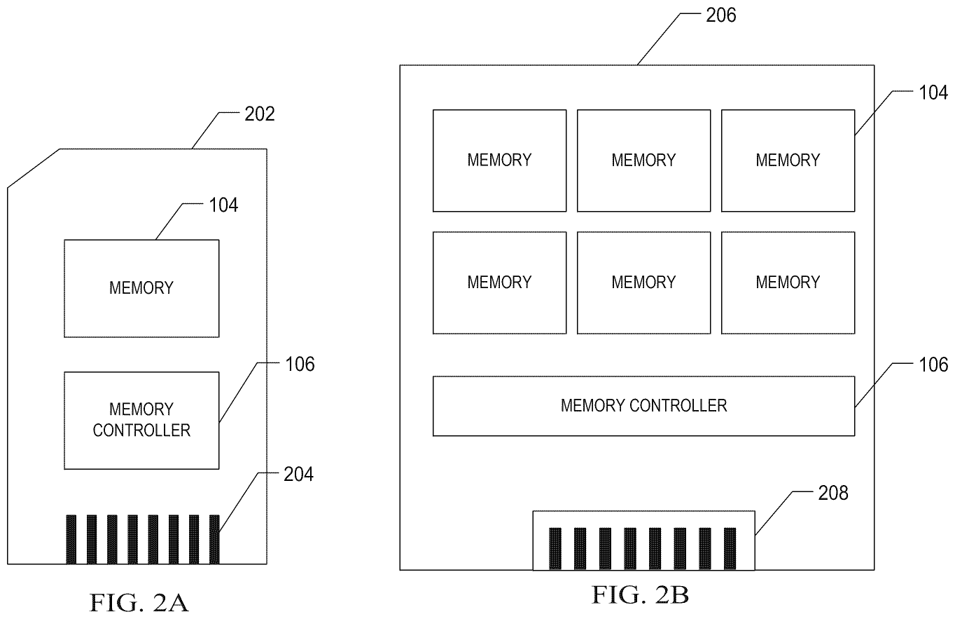

The memory controller 106 and the one or more memories 104 may be integrated into various types of storage apparatuses, e.g., being included in the same package (such as a Universal Flash Storage (abbreviated as UFS) package or an eMMC package). For example, the memory system 102 may be implemented and packaged into different types of terminal electronic products. In an example as shown in FIG. 2A, the memory controller 106 and a single memory 104 may be integrated into a memory card 202. The memory card 202 may include a Personal Computer Memory Card (PC card), a CF card, a Smart Media (abbreviated as SM) card, a memory stick, a Multi-Media Card (MMC, Reduced-Size MMC (RS-MMC), MMCmicro), an SD card (SD, miniSD, microSD, Reduced-Size MMC (SDHC)), and a UFS, etc. The memory card 202 may further include a memory card connector 204 coupling the memory card 202 with a host (e.g., the host 108 in FIG. 1). In another example as shown in FIG. 2B, the memory controller 106 and a plurality of memories 104 may be integrated into an SSD 206. The SSD 206 may further include an SSD connector 208 coupling the SSD 206 with a host (e.g., the host 108 in FIG. 1). In some implementations, at least one of a storage capacity or an operation speed of the SSD 206 is greater than that of the memory card 202.

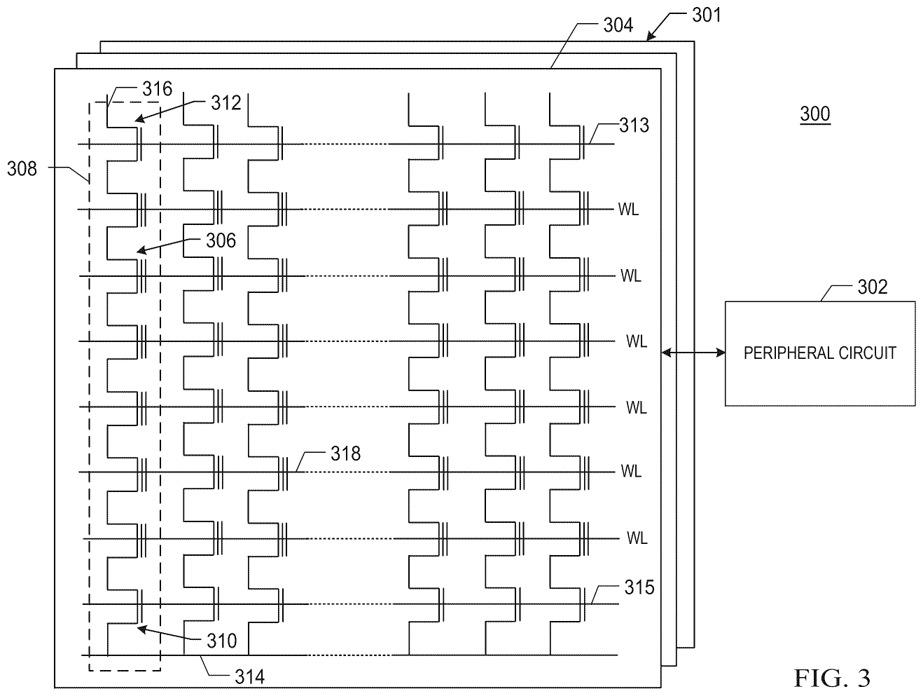

FIG. 3 is a schematic block diagram illustrating a three-dimensional NAND memory 300 according to examples of the present disclosure. The memory 300 may be an example of the memory 104 in FIG. 1. The memory 300 may include a memory cell array 301 and a peripheral circuit 302 coupled to the memory cell array 301. An illustration is performed with an example in which the memory cell array 301 includes a three-dimensional NAND memory cell array, wherein memory cells 306 are provided in an array of NAND memory strings 308, and each NAND memory string 308 extends vertically above a substrate (not shown). In some implementations, each NAND memory string 308 may include a plurality of memory cells 306 coupled in series and stacked vertically. Each memory cell 306 may maintain a continuous analog value, such as voltage or charge, which depends on the number of electrons trapped within a region of the memory cell 306. Each memory cell 306 may be a floating gate type of memory cells that includes a floating gate transistor, or a charge trapping type of memory cells that includes a charge trap transistor.

In some implementations, each memory cell 306 includes a Single Level Cell (abbreviated as SLC) that has two possible memory states and thus may store one bit of data. For example, a first memory state “0” may correspond to a first voltage range, and a second memory state “1” may correspond to a second voltage range. In some implementations, each memory cell 306 includes a Multi Level Cell (abbreviated as MLC) that is capable of storing more than a single bit of data in more than four memory states. For example, the MLC may store two bits per cell, three bits per cell (also referred to as a Triple Level Cell (abbreviated as TLC)), or four bits per cell (also referred to as a Quad Level Cell (abbreviated as QLC)). Each MLC is programmable to adopt a range of possible nominal memory values. In one example, if each MLC stores two bits of data, the MLC is programmable to write one of three possible nominal memory values to the cell, while a fourth nominal memory value other than the three nominal memory values may be used to represent an erase state.

As shown in FIG. 3, each NAND memory string 308 may include a Bottom Select Gate (abbreviated as BSG) 310 at its source terminal and a Top Select Gate (abbreviated as TSG) 312 at its drain terminal. The BSG 310 and the TSG 312 may be configured to activate a selected NAND memory string 308 during read and program operations. In some implementations, sources of the NAND memory strings 308 in the same memory block 304 are coupled through the same Source Line (abbreviated as SL) 314 (e.g., a common SL). For example, according to some implementations, all the NAND memory strings 308 in the same memory block 304 have an Array Common Source (abbreviated as ACS). According to some implementations, the TSG 312 of each NAND memory string 308 is coupled to a respective Bit Line (abbreviated as BL) 316 which data can be read from or written to via an output bus (not shown). In some implementations, each NAND memory string 308 is configured to be selected or unselected by applying a select voltage (e.g., above a threshold voltage of a transistor having the TSG 312) or an unselect voltage (e.g., 0 V) to the respective TSG 312 via one or more TSG lines 313 and/or by applying a select voltage (e.g., above a threshold voltage of a transistor having the BSG 310) or an unselect voltage (e.g., 0 V) to the respective BSG 310 via one or more BSG lines 315.

As shown in FIG. 3, the NAND memory strings 308 may be organized into a plurality of memory blocks 304, and each of the memory blocks 304 may have a common source line 314 (e.g., coupled to the ground). In some implementations, each memory block 304 includes a basic data unit for the erase operation, e.g., all the memory cells 306 on the same memory block 304 are erased at the same time. In order to erase the memory cells 306 in a selected memory block, the source line coupled to the selected memory block as well as an unselected memory block in the same plane as the selected memory block can be biased with an erase voltage (Vers) (such as a high positive voltage (e.g., 20 V or higher)). It is to be understood that in some examples, an erase operation may be performed at a half memory block level, a quarter memory block level, or a level having any suitable number of memory blocks or any suitable fractions of a memory block. The memory cells 306 of adjacent ones of the NAND memory strings 308 may be coupled through a word line 318, and the word line 318 selects which row of memory cells 306 is affected by the read and program operations. In some implementations, the memory cells 306 in the memory block 304 that are coupled to the same word line 318 may constitute at least one physical page. Each word line 318 may include a plurality of control gates (gate electrodes) at each memory cell 306 in the respective physical page and a gate line coupling the control gates.

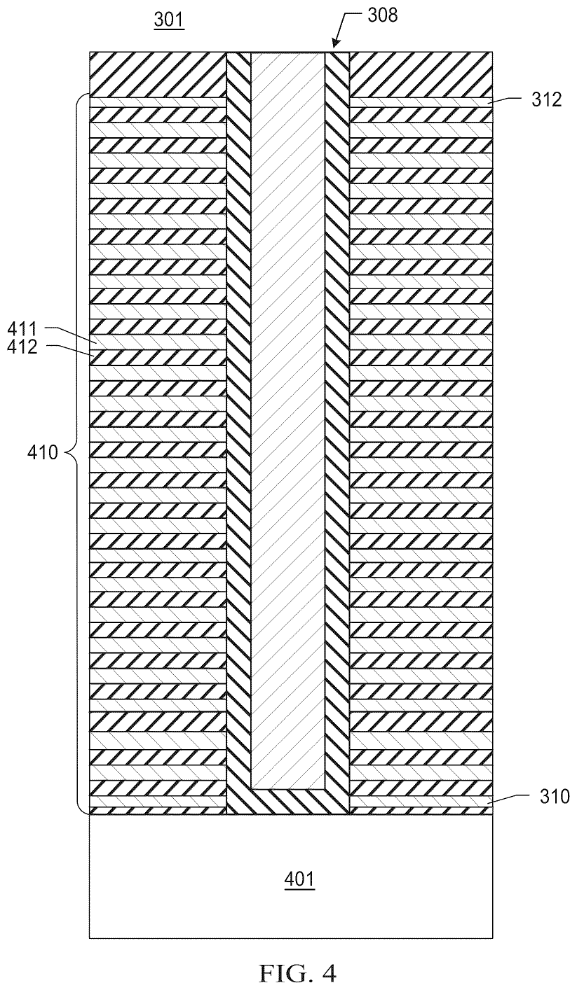

FIG. 4 is a schematic cross-sectional view illustrating a memory according to examples of the present disclosure. With reference to FIG. 4, the NAND memory string 308 may include a stack structure 410 which includes a plurality of gate layers 411 and a plurality of insulation layers 412 that are disposed in a stack alternately and sequentially, and the memory string 308 penetrating through the gate layers 411 and the insulation layers 412 vertically. The gate layers 411 and the insulation layers 412 may be stacked alternately, and two adjacent ones of the gate layers 411 are separated by one insulation layer 412. The number of pairs of the gate layers 411 and the insulation layers 412 in the stack structure 410 may determine the number of memory cells that are included in the memory cell array 301.

A composition material of the gate layers 411 may include a conductive material. The conductive material includes, but is not limited to, tungsten (W), cobalt (Co), copper (Cu), aluminum (A1), polysilicon, doped silicon, silicide, or any combination thereof. In some implementations, each gate layer 411 includes a metal layer, e.g., a tungsten layer. In some implementations, each gate layer 411 includes a doped polysilicon layer. Each gate layer 411 may include a control gate surrounding the memory cells. The gate layer 411 at the top of the stack structure 410 may extend laterally as a top select gate line; the gate layer 411 at the bottom of the stack structure 410 may extend laterally as a bottom select gate line; and the gate layers 411 that extend laterally between the top select gate line and the bottom select gate line may act as word line layers.

In some examples, the stack structure 410 may be disposed on a substrate 401. The substrate 401 may include silicon (e.g., monocrystalline silicon), silicon germanium (SiGe), gallium arsenide (GaAs), germanium (Ge), silicon on insulator (SOI), germanium on insulator (GOI), or any other suitable materials.

In some examples, the NAND memory string 308 includes a channel structure that extends through the stack structure 410 vertically. In some implementations, the channel structure includes a channel hole filled with (one or more) semiconductor materials (e.g., as a semiconductor channel) and (one or more) dielectric materials (e.g., as a memory film). In some implementations, the semiconductor channel includes silicon, e.g., polysilicon. In some implementations, the memory film includes a composite dielectric layer including a tunneling layer, a storage layer (also referred to as a “charge trap/storage layer”), and a barrier layer. The channel structure may have a cylindrical shape (e.g., a pillar shape). According to some implementations, the semiconductor channel, the tunneling layer, the storage layer, and the barrier layer are arranged radially from the center toward the outer surface of the pillar in this order. The tunneling layer may include silicon oxide, silicon oxynitride, or any combination thereof. The storage layer may include silicon nitride, silicon oxynitride, or any combination thereof. The barrier layer may include silicon oxide, silicon oxynitride, a high dielectric constant (high-k) dielectric, or any combination thereof. In an example, the memory film may include a composite layer of silicon oxide/silicon oxynitride/silicon oxide (ONO).

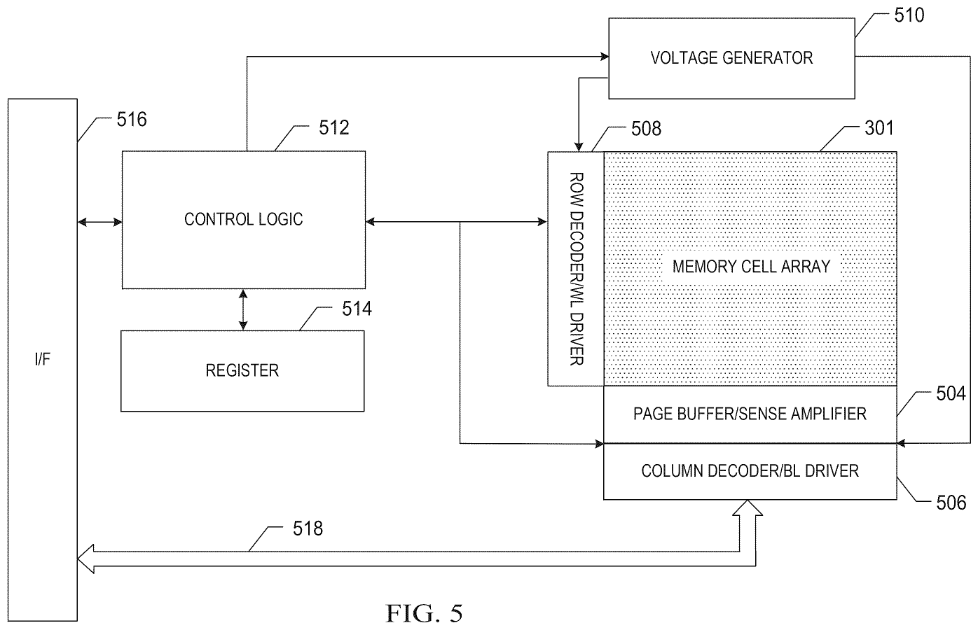

Referring back to FIG. 3, the peripheral circuit 302 may be coupled to the memory cell array 301 through the bit line 316, the word line 318, the source line 314, the BSG line 315 and the TSG line 313. The peripheral circuit 302 may include any suitable analog, digital, and hybrid signal circuits for facilitating operations of the memory cell array 301 by applying voltage signals and/or current signals to each target memory cell 306 and sensing voltage signals and/or current signals from each target memory cell 306 via the bit line 316, the word line 318, the source line 314, the BSG line 315, and the TSG line 313. The peripheral circuit 302 may include various types of peripheral circuits formed using a metal-oxide-semiconductor (MOS) technology. For example, FIG. 5 shows some example peripheral circuits. The peripheral circuit 302 includes a page buffer/sense amplifier 504, a column decoder/bit line driver 506, a row decoder/word line driver 508, a voltage generator 510, a control logic 512, a register 514, an interface 516, and a data bus 518. It is to be understood that in some examples, an additional peripheral circuit not shown in FIG. 5 may also be included.

The page buffer/sense amplifier 504 may be configured to read and program (write) data from and to the memory cell array 301 according to control signals from the control logic 512. In an example, the page buffer/sense amplifier 504 may store one page of program data (write data) to be programmed into one memory page of the memory cell array 301. In another example, the page buffer/sense amplifier 504 may perform a program verify operation to ensure that data is properly programmed into the memory cells 306 that are coupled to the selected word line 318. In yet another example, the page buffer/sense amplifier 504 may also sense low power signals from the bit line 316 that represent data bits stored in the memory cells 306, and amplify a small voltage swing to a recognizable logic level during the read operation. The column decoder/bit line driver 506 may be configured to be controlled by the control logic 512 and select one or more NAND memory strings 308 by applying a bit line voltage generated from the voltage generator 510.

The row decoder/word line driver 508 may be configured to be controlled by the control logic 512, select/unselect the memory block 304 of the memory cell array 301, and select/unselect the word line 318 of the memory block 304. The row decoder/word line driver 508 may be further configured to drive the word line 318 using a word line voltage generated from the voltage generator 510. In some implementations, the row decoder/word line driver 508 may also select/unselect and drive the BSG line 315 and the TSG line 313. As described below in detail, the row decoder/word line driver 508 is configured to perform the program operation on the memory cells 306 that are coupled to (one or more) selected word lines 318. The voltage generator 510 may be configured to be controlled by the control logic 512 and generate the word line voltage (such as a read voltage, a program voltage, a pass voltage, a channel boost voltage, and a verify voltage), the bit line voltage, and a source line voltage to be supplied to the memory cell array 301.

The control logic 512 may be coupled to each peripheral circuit as described above and configured to control operations of each peripheral circuit. The register 514 may be coupled to the control logic 512 and include a state register, a command register, and an address register for storing state information, a command operation code (OP code), and a command address for controlling the operations of each peripheral circuit. The interface 516 may be coupled to the control logic 512, and act as a control buffer to buffer and relay control commands received from a host (not shown) to the control logic 512 and buffer and relay state information received from the control logic 512 to the host. The interface 516 may also be coupled to the column decoder/bit line driver 506 via the data bus 518 and act as a data I/O interface and a data buffer to buffer and relay the data to and from the memory cell array 301.

As stated above, an increase in the storage density leads to more data read problems, such as Read Disturb (abbreviated as RD). In an implementation, during a read operation, a read voltage Vread is applied to a selected word line and a pass voltage Vpass is applied to an unselected word line, and since Vpass is greater than Vread, memory cells coupled with the unselected word line may be programmed slightly. In the case of an excessive read count, an accumulation of slight programming causes a threshold voltage distribution of the memory cells coupled with the unselected word line to shift to the right, resulting in a read error. Single Page Read Disturb (SPRD) affects adjacent word lines greatly, leading to an increase in an error bit count during a read, thereby reducing the reliability of NAND. It is to be pointed out that read disturbance is caused by a physical structure of the NAND itself, and can be alleviated through some methods (e.g., reducing Vpass appropriately). However, the problem cannot be solved at its root.

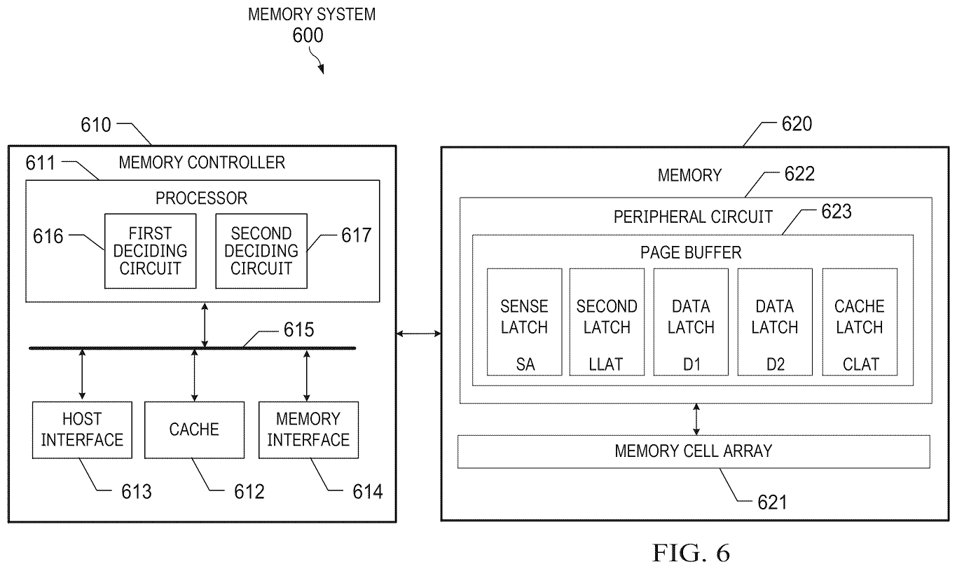

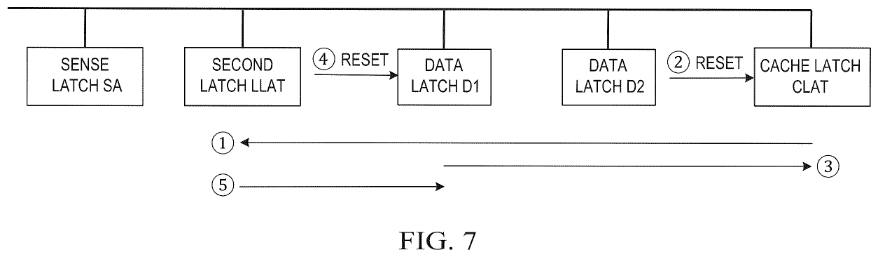

Based on one or more of the above technical problems, examples of the present disclosure provide a memory system. FIG. 6 is a schematic diagram illustrating a memory system according to examples of the present disclosure. FIG. 7 is a schematic diagram of reading stored data from a page buffer according to examples of the present disclosure. An example illustration of the memory system provided by examples of the present disclosure is provided below in conjunction with FIG. 6 and FIG. 7.

With reference to FIG. 6, the memory system 600 includes a memory controller 610 and a memory 620 coupled with the memory controller 610, wherein the memory controller 610 and the memory 620 may be coupled in any appropriate pattern. The memory controller 610 includes a processor 611, a cache 612, a host interface 613, and a memory interface 614, etc. Of course, the memory controller 610 may further include other circuits or modules not shown.

In some examples, the host interface 613 outputs a request and data, etc. received from the host (e.g., the host 108 in FIG. 1) to an internal bus 615, and sends to the host data read from the memory 620, and a response from the processor 611, etc. The memory interface 614 controls processing of writing and reading data, etc. to and from the memory 620 based on an instruction of the processor 611. The processor 611 controls the memory system 600 overall, and the processor 611 is, for example, a central processing unit, or a Micro Processor Unit (MPU), etc. The processor 611 performs control according to a request in the case of receiving the request from the host via the host interface 613. For example, the processor 611 instructs the memory interface 614 to write data to the memory 620 according to a write request from the host. Furthermore, the processor 611 instructs the memory interface 614 to read data from the memory 620 according to a read request from the host.

It is to be noted that the processor 611 described in the examples of the present disclosure may include a plurality of functional modules. Each functional module of the processor 611 may be a software module running on a processor (e.g., a Microcontroller Unit (MCU)) that is part of the processor 611, or may be a hardware module (such as an Integrated Circuit (IC, e.g., an Application-Specific IC (ASIC), and a Field-Programmable Gate Array (FPGA), etc.)) of a Finite State Machine (FSM), or may be a combination of a software module and a hardware module.

In some examples, the memory controller 610 is configured to perform mapping management on data stored in the memory 620. In an implementation, the memory controller 610 may update and maintain an L2P table, wherein each mapping entry in the L2P table may represent a mapping relationship between a logical address and a physical address. When the host sends a read request including a logical address to the memory controller 610, the memory controller 610 may obtain a corresponding physical address based on the L2P table and the logical address in the read request, and read data from the memory 620 according to the physical address and send the data to the host.

In some examples, the memory controller 610 includes a cache 612, and the cache 612 may include, but is not limited to, a Static Random-Access Memory (SRAM). Meanwhile, the memory system 600 further includes a memory configured to store the L2P table, e.g., a Dynamic Random-Access Memory (DRAM), and the memory controller 610 may acquire the L2P table from the DRAM quickly, thereby achieving a high read efficiency. The DRAM may be disposed inside or outside the memory controller 610. Of course, in other examples, the memory system 600 may be of a DRAM-less type, and the L2P table may be stored in a three-dimensional NAND memory, wherein at least a portion of the L2P table is loaded into the cache 612 in the memory controller 610 when the memory system 600 is powered on.

The memory 620 includes a memory cell array 621 and a peripheral circuit 622 coupled with the memory cell array 621, the peripheral circuit 622 including a page buffer 623, and the page buffer 623 being coupled with the memory cell array 621 via a bit line. There may be one or more page buffers 623 in the memory 620, and for ease of illustration, only one page buffer 623 is shown in FIG. 6.

In some examples of the present disclosure, the memory controller 610 is configured to: in response to a first read request including a first logical address, read data from the memory cell array 621, and store the read data through the page buffer 623, wherein the data includes all data stored in a physical page to which a first physical address corresponding to the first logical address points; and in response to a second read request including a second logical address, read data corresponding to the second logical address from the page buffer 623, wherein the second logical address is related to the first logical address.

In this example, in response to the first read request, the memory controller 610 may read out the all data in the physical page to which the first physical address corresponding to the first logical address points, and store the all read data in the page buffer 623; and since the second logical address is related to the first logical address, the memory controller 610 may read relevant data from the page buffer 623 directly when receiving the second read request. It may be understood that during a process of responding to the second read request, read operations performed on the memory cell array 621 are reduced, e.g., a count of applications of respective read operation voltages (e.g., a read voltage Vread applied to a selected word line and a pass voltage Vpass applied to an unselected word line) to word lines is reduced. As such, in a first aspect, the count of applications of respective read operation voltages to word lines is reduced, thereby reducing read disturbance of adjacent word lines and a probability of read errors, which is favorable to the improvement of the reliability of the memory; in a second aspect, reading the relevant data directly from the page buffer may save read time and reduce power consumption; and in a third aspect, an implementation may be performed using the existing page buffer in the memory, without increasing additional hardware costs.

It is to be noted that a read request received by the memory controller 610 is not limited to the second read request and may include other read requests. If a logical address included in the other read requests is also related to the first logical address, an operation similar to that described above may be performed, so as to reduce the read disturbance multiple times, further improving the reliability of the memory. In a particular example, the first read request and the second read request are consecutive read requests.

It is also to be noted that the second logical address being related to the first logical address may be that the second logical address is identical to the first logical address, e.g., the second logical addresses to which the first physical address and a second physical address correspond point to the same physical page. As such, the all data may be read directly from the page buffer 623 directly, without applying the respective read operation voltages to the word lines, thereby avoiding the read disturbance of adjacent word lines. Of course, the second logical address being related to the first logical address may be that the second logical address is partially the same as the first logical address. In the case where the second logical address is partially the same as the first logical address, a portion of the data may be read from the page buffer 623 directly, so as to reduce the count of applications of respective read operation voltages to word lines, thereby reducing the read disturbance of adjacent word lines.

In some examples of the present disclosure, the memory controller 610 is configured to: in response to the first read request, determine the first physical address corresponding to the first logical address, and send a first read command and the first physical address to the peripheral circuit 622; and in response to the second read request, determine the second physical address corresponding to the second logical address, and send a second read command and the second physical address to the peripheral circuit 622; the peripheral circuit 622 is configured to: in response to the first read command and the first physical address, read data of N logical pages stored in the physical page in the memory cell array 621 to which the first physical address points, wherein N is an integer greater than 1; latch the data of N logical pages to N first latches of the page buffer 623 respectively; and in response to the second read command and the second physical address, read the respective logical page data in the N first latches. An example illustration of a process of the memory controller 610 executing the first read request and the second read request is provided below in conjunction with FIG. 5 and FIG. 6.

With reference to FIG. 6, the memory controller 610 may receive the first read request from the outside (e.g., the host 108 in FIG. 1), parse the first read request to obtain the first logical address, search the L2P table based on the first logical address to determine the first physical address, generate a first read instruction, and send the first read instruction and the first physical address to the memory. Here, the first read request may be received via the host interface 613, and the first read instruction and the first physical address may be sent via the memory interface 614.

The peripheral circuit 622 reads the data stored in the physical page in the memory cell array 621 to which the first physical address points based on the received first read command and the first physical address. In an implementation, as shown in FIG. 5, the control logic 512 May control the WL driver 508 to select a target word line (e.g., selected word line) and control the BL driver 506 to select a target bit line (e.g., selected bit line). The control logic 512 may further acquire a respective read operation parameter from the register 514, and control, based on the acquired read operation parameter, the voltage generator 510 to generate a read operation voltage. The WL driver 508 may drive the word line using the read operation voltage (such as a read voltage and a pass voltages) generated from the voltage generator 510, and the BL driver 506 may drive the bit line using the read operation voltage (such as a bit line read voltage and a bit line inhibit voltage) generated from the voltage generator 510. The page buffer 623 reads the data of N logical pages by sensing a current on the bit line and latches the read data of N logical pages in the N first latches respectively. The data of N logical pages may also be output through the interface 516 and returned to the host, so as to complete the first read request. It is to be noted that after the data of N logical pages are returned to the host, the first latches are not reset, but still latch the respective logical page data.

Still referring to FIG. 6, the memory controller 610 receives the second read request from the outside, parses the second read request to obtain the second logical address, searches the L2P table based on the second logical address to determine the second physical address, generates a second read instruction, and sends the second read instruction and the second physical address to the memory. The second read instruction is configured to indicate reading data from at least the page buffer 623. The peripheral circuit 622 directly reads the data of N logical pages latched in the N first latches based on the received second read command and the second physical address. It may be understood that in this example, the second logical address is identical to the first logical address. When the second logical address is partially the same as the first logical address, the peripheral circuit 622 may read a portion of the logical page data from the N first latches and read another portion of the logical page data from the memory cell array 621.

In the example of the present disclosure, the N first latches are used to latch the data of N logical pages, and when the second read request is received, since the second logical address is related to the first logical address, the respective logical page data may be read from the N first latches, thereby reducing the read disturbance and improving the reliability of the memory.

In some examples, the N first latches include (N-1) data latches and a cache latch; the data latch is configured to: latch one of data of (N-1) logical pages in the data of N logical pages; the cache latch is configured to: latch a remaining one of the data of N logical pages; the peripheral circuit 622 is configured to: in response to the second read command and the second physical address, transmit logical page data latched by at least one of the (N-1) data latches to the cache latch, wherein the second read command is configured to indicate reading at least one of the data of (N-1) logical pages; and control the cache latch to output the logical page data transmitted by the at least one data latch. For ease of understanding, an example illustration is provided below with an example in which the memory cell includes a TLC memory cell and the value of N is 3. In practical applications, the memory cell may also be an MLC memory cell or a QLC memory cell, and the value of N may also be 2, 4, or other values.

With reference to FIG. 6, the page buffer 623 includes the first latches, a second latch LLAT, and a sense latch SA; the first latches include a data latch D1, a data latch D2, and the cache latch CLAT. The TLC memory cell is configured to store data of three logical pages, which are Low Page (LP), Middle Page (MP), and Upper Page (UP) respectively. The LP and MP read from selected TLC memory cells may be latched in the data latch D1 and the data latch D2 respectively, and the read UP may be latched in the cache latch CLAT, as shown in FIG. 6.

FIG. 7 illustrates an example of the data latch D1 latching the relevant data. Referring to operation (3) in FIG. 7, the LP latched by the data latch D1 is transmitted to the cache latch CLAT, and the LP transmitted to the cache latch CLAT is output via the data bus 518 and the interface 516 in FIG. 5. It may be understood that an output end of the cache latch CLAT is coupled with the data bus 518.

If the LP latched by the data latch D1 and the MP latched by the data latch D2 are both relevant data, still referring to FIG. 7, the MP latched by the data latch D2 is first transmitted to the cache latch CLAT, the MP transmitted to the cache latch CLAT is transmitted to the data bus 518, and the cache latch CLAT is reset; then the LP latched by the data latch D1 is transmitted to the cache latch CLAT, the LP transmitted to the cache latch CLAT is transmitted to the data bus 518 in FIG. 5, and the MP and LP transmitted to the data bus 518 are output via the interface 516 in FIG. 5.

Similarly, if the LP latched by the data latch D1, the MP latched by the data latch D2, and the UP latched by the cache latch CLAT are all relevant data, an operation similar to that described above may be performed, so as to transmit the UP, the MP, and the LP sequentially to the data bus 518 in FIG. 5 via the cache latch CLAT and output them via the interface 516 in FIG. 5.

In some examples, the peripheral circuit 622 is further configured to: after transmitting the logical page data latched by the at least one data latch to the cache latch, reset the at least one data latch. As illustrated by operation (4) in FIG. 7, the data latch is reset based on a reset signal, so as to clear information latched by the data latch for use in executing other commands.

In some examples, the page buffer 623 further includes a second latch LLAT; the peripheral circuit 622 is further configured to: before transmitting the logical page data latched by the at least one data latch to the cache latch CLAT, control the cache latch CLAT to transmit the remaining data of one logical page latched by the cache latch to the second latch LLAT; and reset the cache latch CLAT.

In order to avoid the occurrence of a read error and an undesired data loss, before performing operation (3) in FIG. 7, operation (1) may be performed first, e.g., transmitting the UP latched by the cache latch CLAT first to the second latch LLAT, then operation (2) is performed, e.g., resetting the cache latch CLAT based on the reset signal, and then the LP latched by the data latch D1 is transmitted to the cache latch CLAT. Here, the second latch LLAT latches no information.

In some examples, the peripheral circuit 622 is further configured to: after resetting the at least one data latch, transmit the remaining data of one logical page latched by the second latch LLAT to the data latch. As illustrated by operation (5) in FIG. 7, the UP latched in the second latch LLAT is transmitted to the data latch D1. Of course, in other examples, the UP may continue to be latched in the second latch LLAT, and the present disclosure imposes no particular limitation thereon.

In some examples, the memory controller 610 is further configured to: decide whether the second logical address is related to the first logical address; and in response to the second logical address being related to the first logical address, read the data stored in the page buffer 623 that corresponds to the second logical address.

In this example, the memory controller 610, when receiving a new read request (e.g., the second read request), may execute different read strategies by deciding whether the second logical address is related to the first logical address. For example, if the second logical address is related to the first logical address, the generated second read instruction is configured to indicate reading data from at least the page buffer 623; conversely, if the second logical address is unrelated to the first logical address, the generated second read instruction is configured to indicate reading data from the memory cell array 621. As such, the different read strategies may be selected by deciding whether the second logical address of the second read request is related to the first logical address of the first read request, which is favorable to the improvement of a read speed.

In some examples, the memory controller 610 includes a first deciding circuit 616 configured to: decide whether the second logical address is related to the first logical address. In an implementation, the first deciding circuit 616 may determine whether the second logical address is related to the first logical address through a comparison therebetween. The first deciding circuit 616 may be a software module running on the processor 611, may be implemented by means of a hardware module, or may be a combination of a software module and a hardware module.

In some examples, the memory controller 610 is further configured to: decide whether the first read request is a single page read request; and in response to the first read request being the single page read request, store the read data into the page buffer 623. Here, the single page read request is configured to indicate reading one of a plurality of logical pages stored by the memory cells, for example, one logical page read from the TLC memory cells may be any one of the LP, the MP, and the UP.

It is to be pointed out that existing solutions to the SPRD mainly include increasing background scan of adjacent word lines at locations generating the SPRD or decreasing a block refresh threshold. The idea of each of the above solutions is performing a refresh as early as possible before the error bit count exceeds a decoding limit. However, frequent refreshes cause some performance overheads.

In this example, the memory controller 610 decides whether the first read request is the single page read request, and stores the read data into the page buffer 623 when the first read request is the single page read request, so as to avoid serious read disturbance in an SPRD scenario, solving the problem from the source of generating the read disturbance, greatly reducing a rise rate of a fail bit count in the SPRD scenario, and thereby reducing a read retry count and a refresh count, which is favorable to a reduction of firmware overheads.

In some other examples, first read requests may also be a plurality of logical page read requests, and the plurality of logical page read requests are used to indicate reading at least two of the plurality of logical pages stored by the memory cells. The number of the read at least two logical pages may be less than the number of bits stored by each memory cell, and logical addresses of the read at least two logical pages are consecutive and located at the same memory cell layer. For example, the read at least two logical pages in the TLC memory cell may be any two of the LP, the MP, and the UP.

In some examples, the memory controller 610 includes a second deciding circuit 617 configured to: decide whether the first read command is the single page read request. The second deciding circuit 617 may be a software module running on the processor 611, may be implemented by means of a hardware module, or may be a combination of a software module and a hardware module.

In some examples, the memory controller 610 is configured to: in response to the first read request being the single page read request, send to the peripheral circuit 622 a command of storing the read data into the page buffer 623.

In this example, the read data of one logical page may be latched to a spare latch of the page buffer 623 and then output via the cache latch CLAT, and the data bus 518 and the interface 516 in FIG. 5. The memory controller 610 may generate a set feature command, which is configured to indicate storing the read data of one logical page into the page buffer 623. For example, the spare latch that latches the read data of one logical page is not reset and continues to latch the data of one logical page. Here, when the read data of one logical page is latched in the cache latch CLAT, the data of one logical page is output directly via the data bus 518 and the interface 516.

It is to be noted that the set feature command may be included in the first read command, for example, the first read command includes an identifier indicating storing the read data into the page buffer. The set feature command may also be a command set specially, and the set feature command is callable in the SPRD scenario.

Based on the above-mentioned memory system, examples of the present disclosure further provide a method of operating a memory system.

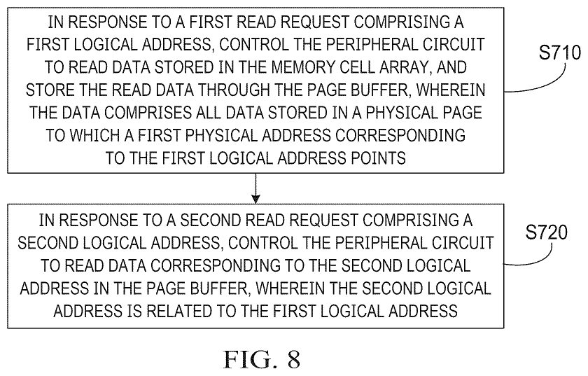

FIG. 8 is a flow diagram illustrating a method of operating a memory system according to examples of the present disclosure. The memory system may be the memory system 600 in any of the above examples, and the method includes at least the following operations:
S710: in response to a first read request including a first logical address, controlling the peripheral circuit to read data stored in the memory cell array, and storing the read data through the page buffer, wherein the data includes all data stored in a physical page to which a first physical address corresponding to the first logical address points; and
S720: in response to a second read request including a second logical address, controlling the peripheral circuit to read data corresponding to the second logical address in the page buffer, wherein the second logical address is related to the first logical address.

In some examples, the controlling the peripheral circuit to read data stored in the memory cell array, and storing the read data through the page buffer in response to a first read request including a first logical address includes: in response to the first read request, determining the first physical address corresponding to the first logical address, and sending a first read command and the first physical address to the peripheral circuit; in response to the first read command and the first physical address, reading, by the peripheral circuit, data of N logical pages stored in the physical page in the memory cell array to which the first physical address points, wherein N is an integer greater than 1; and latching, by the peripheral circuit, the data of N logical pages to N first latches of the page buffer respectively; and the controlling the peripheral circuit to read data corresponding to the second logical address in the page buffer in response to a second read request including a second logical address includes: in response to the second read request, determining a second physical address corresponding to the second logical address, and sending a second read command and the second physical address to the peripheral circuit; and in response to the second read command and the second physical address, reading, by the peripheral circuit, the respective logical page data in the N first latches.

In some examples, the N first latches include (N-1) data latches and a cache latch; the method further includes: latching, by each data latch, one of data of (N-1) logical pages in the data of N logical pages; latching, by the cache latch, a remaining one of the data of N logical pages; the reading, by the peripheral circuit, the respective logical page data in the N first latches in response to the second read command and the second physical address includes: in response to the second read command and the second physical address, controlling, by the peripheral circuit, at least one of the (N-1) data latches to transmit logical page data latched by the at least one data latch to the cache latch, wherein the second read command is configured to indicate reading at least one of the data of (N-1) logical pages; and controlling, by the peripheral circuit, the cache latch to output the logical page data transmitted by the at least one data latch.

In some examples, the method further includes: after transmitting the logical page data latched by the at least one data latch to the cache latch, resetting, by the peripheral circuit, the at least one data latch.

In some examples, the page buffer further includes a second latch; the method further includes: before transmitting the logical page data latched by the at least one data latch to the cache latch, controlling, by the peripheral circuit, the cache latch to transmit the remaining data of one logical page latched by the cache latch to the second latch; and resetting, by the peripheral circuit, the cache latch.

In some examples, the method further includes: after resetting the at least one data latch, transmitting, by the peripheral circuit, the remaining data of one logical page latched by the second latch to the data latch.

In some examples, the method further includes: deciding whether the second logical address is related to the first logical address; and in response to the second logical address being related to the first logical address, reading the data stored in the page buffer that corresponds to the second logical address.

In some examples, the method further includes: deciding whether the first read request is a single page read request; and in response to the first read request being the single page read request, storing the read data into the page buffer.

In some examples, the storing the read data to the page buffer in response to the first read request being a single page read request includes: in response to the first read request being the single page read request, sending to the peripheral circuit a command of storing the read data into the page buffer.

In the examples of the present disclosure, the method of a memory system may be performed by the memory controller in the memory system in any of the above examples, and the technical effects that can be realized by the memory system in the above examples all can be realized by the method of a memory system, which are no longer repeated one by one here. An example implementation of each operation of the method in the above examples is described in detail in related device examples, which is no longer set forth in detail here.

Based on the above-mentioned memory system, examples of present disclosure further provide an electronic device including the memory system as described in any of the above examples; and a host coupled with the memory system.

Based on the above-mentioned memory system, examples of the present disclosure further provide a computer readable storage medium storing instructions that, when executed by a processor, implement the method of any of the above examples.

Here, all or part of the processes in the method of the above examples may be implemented by hardware related to instructions (e.g., a computer program). The computer program may be stored in a computer readable storage medium, and the execution of the computer program may include the processes of the method in any of the above examples. The computer readable storage medium may be a magnetic disk, an optical disk, a Read-Only Memory (ROM), a Random Access Memory (RAM), a Flash Memory, a Hard Disk Drive (HDD), or a solid-state disk, etc. The computer readable storage medium may further include a combination of a plurality of storage medium described above.

It is to be understood that “one example” and “an example” mentioned throughout the specification mean that specific features, structures or characteristics related to the example are included in at least one example of the present disclosure. Therefore, “in one example” or “in an example” appearing at any place throughout specification does not always refer to the same example. In addition, these specific features, structures or characteristics may be combined in one or more examples in any proper manner. It is to be understood that, in various examples of the present disclosure, the sequence number of each process does not mean the sequence of execution. The execution sequence of each process should be determined by its functions and internal logic, which should not constitute any limitation on the implementation process of the examples of the present disclosure. The serial numbers of above examples of the present disclosure are merely for description, and do not represent the superiority or inferiority of the examples.

It is to be noted that term “include”, and “comprise” or any other variant thereof is intended to cover nonexclusive inclusions herein, so that a process, method, object or device comprising a series of elements not only comprises those elements but also comprises other elements which are not clearly listed or further comprises elements intrinsic to the process, the method, the object or the device. In the case of no more limitations, an element defined by the statement “including a/an . . . ” does not exclude the existence of another identical element in a process, method, object or device comprising the element.

The above descriptions are merely implementations of the present disclosure, and the protection scope of the present disclosure is not limited thereto. Any variation or replacement that may be readily figured out by those skilled in the art within the technical scope disclosed by the present disclosure shall fall within the protection scope of the present disclosure.

What is claimed is:

1. A memory system, comprising:
a memory comprising:
a memory cell array; and
a peripheral circuit coupled with the memory cell array, the peripheral circuit comprising a page buffer; and
a memory controller coupled with the memory and configured to:
in response to a first read request comprising a first logical address, read data from the memory cell array, and store the read data through the page buffer, wherein the data comprises all data stored in a physical page to which a first physical address corresponding to the first logical address points; and
in response to a second read request comprising a second logical address, read data corresponding to the second logical address from the page buffer, wherein the second logical address is related to the first logical address.

2. The memory system of claim 1, wherein the memory controller is configured to:
in response to the first read request, determine the first physical address corresponding to the first logical address, and send a first read command and the first physical address to the peripheral circuit; and
in response to the second read request, determine a second physical address corresponding to the second logical address, and send a second read command and the second physical address to the peripheral circuit;
the peripheral circuit is configured to:
in response to the first read command and the first physical address, read data of N logical pages stored in the physical page in the memory cell array to which the first physical address points, wherein N is an integer greater than 1;
latch the data of N logical pages to N first latches of the page buffer respectively; and
in response to the second read command and the second physical address, read the respective logical page data in the N first latches.

3. The memory system of claim 2, wherein
the N first latches comprise:
(N-1) data latches, each of which configured to: latch data of one logical page in data of (N-1) logical pages in the data of the N logical pages; and
a cache latch configured to: latch a remaining one of the data of N logical pages;
the peripheral circuit is configured to:
in response to the second read command and the second physical address, transmit logical page data latched by at least one of the (N-1) data latches to the cache latch, wherein the second read command is configured to indicate reading at least one of the data of (N-1) logical pages; and
control the cache latch to output the logical page data transmitted by the at least one data latch.

4. The memory system of claim 3, wherein the peripheral circuit is further configured to:
after transmitting the logical page data latched by the at least one data latch to the cache latch, reset the at least one data latch.

5. The memory system of claim 4, wherein the page buffer further comprises a second latch;
the peripheral circuit is further configured to:
before transmitting the logical page data latched by the at least one data latch to the cache latch, control the cache latch to transmit the latched remaining data of one logical page to the second latch; and
reset the cache latch.

6. The memory system of claim 5, wherein the peripheral circuit is further configured to:
after resetting the at least one data latch, transmit the remaining data of one logical page latched by the second latch to the data latch.

7. The memory system of claim 1, wherein the memory controller is further configured to:
decide whether the second logical address is related to the first logical address; and
in response to the second logical address being related to the first logical address, read the data stored in the page buffer that corresponds to the second logical address.

8. The memory system of claim 1, wherein the memory controller is further configured to:
decide whether the first read request is a single page read request; and
in response to the first read request being the single page read request, store the read data into the page buffer.

9. The memory system of claim 8, wherein the memory controller is configured to:
in response to the first read request being the single page read request, send to the peripheral circuit a command of storing the read data into the page buffer.

10. The memory system of claim 8, wherein the memory controller comprises:
a first deciding circuit configured to: decide whether the second logical address is related to the first logical address; and
a second deciding circuit configured to: decide whether the first read command is the single page read request.

11. The memory system of claim 1, wherein the second logical address being related to the first logical address comprises:
the first physical address and a second physical address corresponding to the second logical address point to the same physical page.

12. A method of operating a memory system, wherein the memory system comprises a memory and a memory controller coupled with the memory; the memory comprises a memory cell array and a peripheral circuit coupled with the memory cell array, the peripheral circuit comprising a page buffer; the method comprising:
in response to a first read request comprising a first logical address, controlling the peripheral circuit to read data stored in the memory cell array, and storing the read data through the page buffer, wherein the data comprises all data stored in a physical page to which a first physical address corresponding to the first logical address points; and
in response to a second read request comprising a second logical address, controlling the peripheral circuit to read data corresponding to the second logical address in the page buffer, wherein the second logical address is related to the first logical address.

13. The method of claim 12, wherein
controlling the peripheral circuit to read data stored in the memory cell array, and storing the read data through the page buffer comprises:
in response to the first read request, determining the first physical address corresponding to the first logical address, and sending a first read command and the first physical address to the peripheral circuit; in response to the first read command and the first physical address, reading, by the peripheral circuit, data of N logical pages stored in the physical page in the memory cell array to which the first physical address points, wherein N is an integer greater than 1; and latching, by the peripheral circuit, the data of N logical pages to N first latches of the page buffer respectively; and
controlling the peripheral circuit to read data corresponding to the second logical address in the page buffer in response to a second read request comprising a second logical address comprises:
in response to the second read request, determining a second physical address corresponding to the second logical address, and sending a second read command and the second physical address to the peripheral circuit; and
in response to the second read command and the second physical address, reading, by the peripheral circuit, the respective logical page data in the N first latches.

14. The method of claim 13, wherein the N first latches comprise (N-1) data latches and a cache latch; the method further comprising:
latching, by the data latch, one of data of (N-1) logical pages in the data of N logical pages; and
latching, by the cache latch, a remaining one of the data of N logical pages; and
reading, by the peripheral circuit, the respective logical page data in the N first latches in response to the second read command and the second physical address comprises:
in response to the second read command and the second physical address, controlling, by the peripheral circuit, at least one of the (N-1) data latches to transmit the latched logical page data to the cache latch, wherein the second read command is configured to indicate reading at least one of the data of (N-1) logical pages; and
controlling, by the peripheral circuit, the cache latch to output the logical page data transmitted by the at least one data latch.

15. The method of claim 14, further comprising:
after transmitting the logical page data latched by the at least one data latch to the cache latch, resetting, by the peripheral circuit, the at least one data latch.

16. The method of claim 15, wherein the page buffer further comprises a second latch; the method further comprising:
before transmitting the logical page data latched by the at least one data latch to the cache latch, controlling, by the peripheral circuit, the cache latch to transmit the latched remaining data of one logical page to the second latch; and
resetting, by the peripheral circuit, the cache latch.

17. The method of claim 16, further comprising:
after resetting the at least one data latch, transmitting, by the peripheral circuit, the remaining data of one logical page latched by the second latch to the data latch.

18. The method of claim 12, further comprising:
deciding whether the second logical address is related to the first logical address; and
in response to the second logical address being related to the first logical address, reading the data stored in the page buffer that corresponds to the second logical address.

19. The method of claim 12, further comprising:
deciding whether the first read request is a single page read request; and
in response to the first read request being the single page read request, storing the read data into the page buffer.

20. An electronic apparatus, comprising:
a memory system, comprising:
a memory comprising:
a memory cell array; and
a peripheral circuit coupled with the memory cell array, the peripheral circuit comprising a page buffer;
a memory controller coupled with the memory and configured to:
in response to a first read request comprising a first logical address, read data from the memory cell array, and store the read data through the page buffer, wherein the data comprises all data stored in a physical page to which a first physical address corresponding to the first logical address points; and
in response to a second read request comprising a second logical address, read data corresponding to the second logical address from the page buffer, wherein the second logical address is related to the first logical address; and
a host coupled with the memory system.
